(19) United States
(12) Patent Application Publication
(10) Pub. No.: US 2023/0013404 A1
(43) Pub. Date: Jan. 19, 2023

(54) LAMINATED SHEET FOR METAL-CLAD LAMINATE, METHOD OF MANUFACTURING LAMINATED SHEET FOR METAL-CLAD LAMINATE, METAL-CLAD LAMINATE, AND METHOD OF MANUFACTURING METAL-CLAD LAMINATE

(71) Applicant: FUJIFILM Corporation, Tokyo (JP)

(72) Inventors: Takahiko ICHIKI, Shizuoka (JP); Yoshihiko MOCHIZUKI, Shizuoka (JP)

(73) Assignee: FUJIFILM Corporation, Tokyo (JP)

(21) Appl. No.: 17/947,171

(22) Filed: Sep. 19, 2022

Related U.S. Application Data
(63) Continuation of application No. PCT/JP2021/012762, filed on Mar. 26, 2021.

(30) Foreign Application Priority Data
Mar. 31, 2020 (JP) 2020-062850

(51) Int. Cl. B32B 15/08; H05K 3/02; H05K 1/03; C23C 16/40; B32B 7/12; B32B 15/20

(52) U.S. Cl. CPC B32B 15/08; H05K 3/022; H05K 1/036; C23C 16/401; B32B 7/12; B32B 15/20; H05K 2201/0141; H05K 2201/015; H05K 2201/0175; H05K 2201/0179; H05K 2201/0209; B32B 2255/20; B32B 2255/10; B32B 2457/08

(57) ABSTRACT

An object of the present invention is to provide a laminated sheet for a metal-clad laminate and a method of manufacturing the same, the laminated sheet including: a substrate that includes a liquid crystal polymer or a fluoropolymer; and an adhesive layer, in which adhesiveness with a metal layer formed on the adhesive layer is excellent. Another object of the present invention is to provide a metal-clad laminate and a method of manufacturing the same.

A laminated sheet for a metal-clad laminate includes: a substrate that includes a liquid crystal polymer or a fluoropolymer; an inorganic oxide layer; and an adhesive layer, in which the substrate, the inorganic oxide layer, and the adhesive layer are laminated in this order.

### CROSS-REFERENCE TO RELATED APPLICATIONS

This application is a Continuation of PCT International Application No. PCT/JP2021/012762 filed on Mar. 26, 2021, which claims priority under 35 U.S.C. § 119(a) to Japanese Patent Application No. 2020-062850 filed on Mar. 31, 2020. The above application is hereby expressly incorporated by reference, in its entirety, into the present application.

### BACKGROUND OF THE INVENTION

### 1. Field of the Invention

The present invention relates to a laminated sheet for a metal-clad laminate, a method of manufacturing a laminated sheet for a metal-clad laminate, a metal-clad laminate, and a method of manufacturing a metal-clad laminate.

### 2. Description of the Related Art

In the fifth generation (5G) mobile communication system called the next generation communication technology, a higher frequency and a wider bandwidth are required than before. Therefore, as a substrate film for a circuit board in a 5G mobile communication system, a film having properties such as low dielectric constant and low dielectric loss tangent is required, and various materials have been developed.

Examples of such a substrate film include a polymer film including a liquid crystal polymer (LCP). The polymer film including a liquid crystal polymer has a lower dielectric constant and a lower dielectric loss tangent than polyimide and a glass epoxy film that are generally used as a substrate film for a circuit board in a fourth generation (4G) mobile communication system.

For example, WO2018/163999A discloses a metal-clad laminate where an adhesive layer and a metal foil are laminated in this order on a single surface of a liquid crystal polymer film.

### SUMMARY OF THE INVENTION

The present inventors investigated the metal-clad laminate described in WO2018/163999A and clarified that adhesiveness of the metal foil is not always sufficient and there is a room for further improvement.

As the film having the above-described properties such as low dielectric constant and low dielectric loss tangent, in addition to the liquid crystal polymer film, a film including a fluoropolymer also attracts attention.

Therefore, an object of the present invention is to provide a laminated sheet for a metal-clad laminate and a method of manufacturing the same, the laminated sheet including: a substrate that includes a liquid crystal polymer or a fluoropolymer; and an adhesive layer, in which adhesiveness with a metal layer formed on the adhesive layer is excellent.

In addition, another object of the present invention is to provide a metal-clad laminate and a method of manufacturing the same.

The present inventors found that the object can be achieved by the following configurations.

[1] A laminated sheet for a metal-clad laminate comprising:

a substrate that includes a liquid crystal polymer or a fluoropolymer;

an inorganic oxide layer; and

an adhesive layer,

in which the substrate, the inorganic oxide layer, and the adhesive layer are laminated in this order.

[2] The laminated sheet for a metal-clad laminate according to [1], in which the adhesive layer includes a resin as a major component.

[3] The laminated sheet for a metal-clad laminate according to [1] or [2],

in which the adhesive layer is in the B stage.

[4] The laminated sheet for a metal-clad laminate according to any one of [1] to [3],

in which in the inorganic oxide layer, an atom having a highest content among components selected from metal atoms and metalloid atoms is a silicon atom.

[5] A method of manufacturing a laminated sheet for a metal-clad laminate, the method comprising:

an inorganic oxide layer forming step of forming an inorganic oxide layer using a plasma chemical vapor deposition method on a surface of a substrate that includes a liquid crystal polymer or a fluoropolymer; and

an adhesive layer forming step of forming an adhesive layer on the inorganic oxide layer.

[6] The method of manufacturing a laminated sheet for a metal-clad laminate according to [5],

in which the inorganic oxide layer is formed using a raw material gas including tetraethoxysilane as a major component.

[7] The method of manufacturing a laminated sheet for a metal-clad laminate according to [5] or [6],

in which the plasma chemical vapor deposition method is an atmospheric pressure plasma chemical vapor deposition method.

[8] The method of manufacturing a laminated sheet for a metal-clad laminate according to any one of [5] to [7],

in which the adhesive layer includes a resin as a major component.

[9] The method of manufacturing a laminated sheet for a metal-clad laminate according to any one of [5] to [8],

in which the adhesive layer is in the B stage.

[10] A method of manufacturing a metal-clad laminate, the method comprising:

a metal layer forming step of forming a metal layer by thermally pressure-bonding a metal foil to the adhesive layer in the laminated sheet for a metal-clad laminate according to any one of [1] to [4].

[11] A method of manufacturing a metal-clad laminate, the method comprising:

a step of manufacturing a laminated sheet for a metal-clad laminate using the method of manufacturing a laminated sheet for a metal-clad laminate according to any one of [5] to [9]; and

a metal layer forming step of forming a metal layer by thermally pressure-bonding a metal foil to the adhesive layer in the laminated sheet for a metal-clad laminate.

[12] A metal-clad laminate comprising:

a substrate that includes a liquid crystal polymer or a fluoropolymer;

an inorganic oxide layer;

a resin layer; and

a metal layer,

in which the substrate, the inorganic oxide layer, and the metal layer are laminated in this order.

According to the present invention, it is possible to provide a laminated sheet for a metal-clad laminate and a method of manufacturing the same, the laminated sheet including: a substrate that includes a liquid crystal polymer or a fluoropolymer; and an adhesive layer, in which adhesiveness with a metal layer formed on the adhesive layer is excellent.

In addition, according to the present invention, it is also possible to provide a metal-clad laminate and a method of manufacturing the same.

### BRIEF DESCRIPTION OF THE DRAWINGS

FIG. 1 is a schematic diagram showing an example of an embodiment of a laminated sheet for a metal-clad laminate.

FIG. 2 is a schematic diagram showing an example of an embodiment of a metal-clad laminate.

### DESCRIPTION OF THE PREFERRED EMBODIMENTS

Hereinafter, the details of the present invention will be described.

In the present specification, numerical ranges represented by “to” include numerical values before and after “to” as lower limit values and upper limit values.

In addition, regarding numerical ranges that are described stepwise in the present specification, an upper limit value or a lower limit value described in a numerical value may be replaced with an upper limit value or a lower limit value of another stepwise numerical range. In addition, regarding a numerical range described in the present specification, an upper limit value or a lower limit value described in a numerical value may be replaced with a value described in Examples.

[Laminated Sheet for Metal-Clad Laminate and Method of Manufacturing the Same]

For example, one feature point of the laminated sheet for a metal-clad laminate according to the embodiment of the present invention is that an inorganic oxide layer is provided between a substrate that includes a liquid crystal polymer or a fluoropolymer and an adhesive layer.

In a metal-clad laminate formed using the laminated sheet for a metal-clad laminate according to the embodiment of the present invention having the above-described configuration, adhesiveness with a metal layer is high.

The action mechanism between the configuration and the effect is not clear, but the present inventors presume that the action mechanism is as follows. The liquid crystal polymer and the fluoropolymer have low surface energy due to their hydrophobic structure. Therefore, the substrate that includes the liquid crystal polymer or the fluoropolymer has a problem in that adhesiveness with a metal layer formed of a metallic material of a metal foil. On the other hand, in a method of introducing an adhesive layer between a substrate and a metal layer as in WO2018/163999A, adhesiveness can be improved to some extent. However, it is not easy to achieve a peel strength (typically, 7 N/cm or higher) required for use in a printed wiring board or the like. According to a recent investigation, the present inventor found that the above-described problem occurs because adhesiveness between a substrate that includes a liquid crystal polymer or a fluoropolymer and a resin layer obtained by curing an adhesive layer is poor. Therefore, in the above-described laminated sheet for a metal-clad laminate, by disposing the inorganic oxide layer between the substrate and the adhesive layer, adhesiveness between the resin layer (corresponding to the cured resin layer) obtained by curing the adhesive layer and the substrate that includes a liquid crystal polymer or a fluoropolymer is improved.

Examples of a method of forming the inorganic oxide layer include a method of forming a silicon oxide film on a surface of the substrate with a plasma chemical vapor deposition method (preferably an atmospheric pressure plasma chemical vapor deposition method) using a raw material gas including an organic silicon compound as described below. This method is particularly suitable for forming an inorganic oxide layer on a substrate that includes a liquid crystal polymer. The substrate that includes a liquid crystal polymer is configured by stacking molecules having a linear structure in a planar shape. In a case where a plasma surface treatment is performed on the substrate to improve adhesiveness, the molecular weight of liquid crystal molecules on the plasma-treated surface tends to decrease such that cohesion failure occurs. On the other hand, in a case where the plasma chemical vapor deposition method using the raw material gas including an organic silicon compound, in the process in which the molecular weight of the liquid crystal molecules on the plasma-treated surface decreases, it is presumed that a chemical bond between silicon atoms and the liquid crystal molecules is newly formed. It is also presumed that, as a result of the formation of the chemical bond, cohesion failure caused by a decrease in the molecular weight of the liquid crystal molecules is suppressed. That is, with the above-described method, the inorganic oxide layer can be formed on the substrate that includes a liquid crystal polymer while suppressing cohesion failure, and thus a higher peel strength can be achieved.

Hereinafter, the configuration of the laminated sheet for a metal-clad laminate according to the embodiment of the present invention will be described in detail. In addition, this manufacturing method will also be described in detail.

[Laminated Sheet for Metal-Clad Laminate According to First Embodiment]

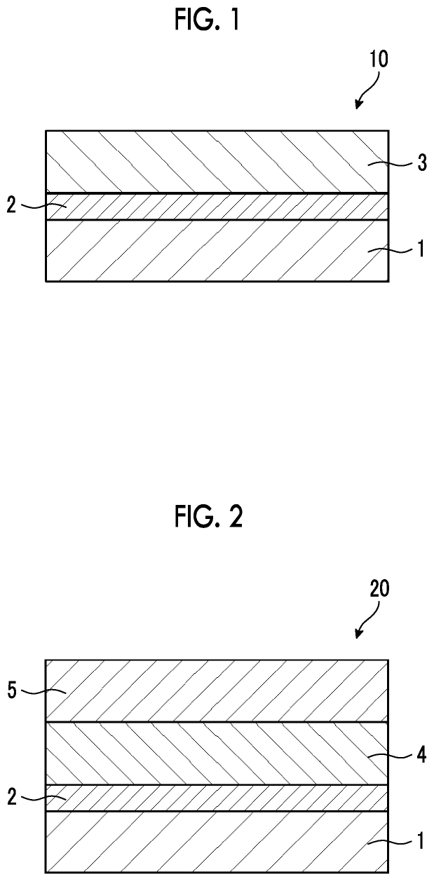

FIG. 1 is a cross-sectional view showing one embodiment of the laminated sheet for a metal-clad laminate.

A laminated sheet 10 for a metal-clad laminate includes a substrate 1 that includes a liquid crystal polymer or a fluoropolymer, an inorganic oxide layer 2, and an adhesive layer 3 in this order.

A protective film may be disposed on a surface of the adhesive layer 3 opposite to the inorganic oxide layer 2.

The laminated sheet for a metal-clad laminate is a member that can be used for manufacturing a metal-clad laminate described below. In a case where a metal-clad laminate is manufactured using the laminated sheet 10 for a metal-clad laminate, a metal layer is laminated on a surface of the adhesive layer 3 opposite to the inorganic oxide layer in the laminated sheet 10 for a metal-clad laminate. That is, the surface of the adhesive layer 3 opposite to the inorganic oxide layer 2 is an adhesion surface (preferably, a thermal pressure bonding surface) with a metallic material (for example, a metal foil) for forming the metal layer.

Hereinafter, configurations of the substrate 1, the inorganic oxide layer 2, and the adhesive layer 3 forming the laminated sheet 10 for a metal-clad laminate will be described in detail.

<Substrate>

The substrate may have any shape of a sheet shape, a film shape, or a plate shape.

From the viewpoint of further improving the strength and/or from the viewpoint of further improving insulating properties between layers in a case where the present invention is applied to a multilayered circuit board, the lower limit value of the thickness of the substrate is preferably 5 μm or more and more preferably 12 μm or more. In addition, from the viewpoint of further improving workability, the upper limit value is preferably 130 μm or less, more preferably 100 μm or less, still more preferably 80 μm or less, and still more preferably 60 μm or less.

The substrate includes a liquid crystal polymer or a fluoropolymer. Hereinafter, the substrate that includes a liquid crystal polymer will also be referred to as “liquid crystal polymer substrate”. In addition, the substrate that includes a fluoropolymer will also be referred to as “fluoropolymer substrate”.

(Liquid Crystal Polymer Substrate)

Examples of the liquid crystal polymer include a thermotropic liquid crystal polymer that is liquid crystalline in a molten state and a lyotropic liquid crystal polymer that is liquid crystalline in a solution state. The liquid crystal polymer may be in any form. From the viewpoints of being thermoplastic and further improving dielectric characteristics, the thermotropic liquid crystal polymer is preferable. As long as the thermotropic liquid crystal polymer is a liquid crystal polymer that is melt-moldable, a chemical composition thereof is not particularly limited and examples thereof include a thermoplastic liquid crystal polyester and a thermoplastic liquid crystal polyester obtained by introducing an amide bond into a thermoplastic liquid crystal polyester. Examples of the thermotropic liquid crystal polymer include liquid crystal polymers described in paragraphs “0023” and “0024” of WO2018/163999A and a thermoplastic liquid crystal polymer described in WO2015/064437A.

In addition, as the liquid crystal polymer, a commercially available product may be used, and examples thereof include LAPEROS (trade name) manufactured by Polyplastics Co., Ltd.

The content of the liquid crystal polymer in the liquid crystal polymer substrate with respect to the total mass of the liquid crystal polymer substrate is preferably 40 mass % or more and more preferably 60 mass % or more and, from the viewpoint of further improving dielectric characteristics, is still more preferably 80 mass % or more. The upper limit value is, for example, 100 mass % or less and is preferably 99 mass % or less and more preferably 97 mass % or less.

The liquid crystal polymer substrate may include an inorganic filler. In a case where shear stress is applied to the liquid crystal polymer, the liquid crystal polymer exhibits anisotropy. Therefore, in the manufacturing of the liquid crystal polymer substrate, an inorganic filler may be added to alleviate the anisotropy of molecular alignment that occurs in a case where the liquid crystal polymer is melted. The inorganic filler is not particularly limited, and examples thereof include talc, mica, aluminum oxide, titanium oxide, silicon oxide, silicon nitride, and carbon black.

The shape of the inorganic filler is not particularly limited, and examples thereof include a spherical shape, a plate shape, a rod shape, an acicular shape, and an unstructured shape. In addition, the average particle diameter (volume average particle size) of the inorganic filler is not particularly limited and is preferably 0.050 to 10 μm.

The content of the inorganic filler in the liquid crystal polymer substrate with respect to the total mass of the liquid crystal polymer substrate is, for example, 0.5 mass % or more, preferably 1 mass % or more, and more preferably 1.5 mass % or more. From the viewpoint of securing dielectric characteristics, the upper limit value of the content of the inorganic filler with respect to the total mass of the liquid crystal polymer substrate is preferably 20 mass % or less and more preferably 15 mass % or less.

In addition, the liquid crystal polymer substrate may include a polymer other than the liquid crystal polymer. Examples of the other polymer include a thermoplastic resin and an elastomer. The elastomer refers to a polymer compound that exhibits elastic deformation. That is, the elastomer corresponds to a polymer compound that is deformed in a case where an external force is applied and that is restored to the original shape in a case where the external force is released.

Examples of the thermoplastic resin include a polyurethane resin, a polyester resin, a (meth)acrylic resin, a polystyrene resin, a fluororesin, a polyimide resin, a fluorinated polyimide resin, a polyamide resin, a polyamide imide resin, a polyether imide resin, a cellulose acylate resin, a polyether ether ketone resin, a polycarbonate resin, a polyolefin resin (for example, a polyethylene resin, a polypropylene resin, a resin formed of a cyclic olefin copolymer, or an alicyclic polyolefin resin), a polyarylate resin, a polyethersulfone resin, a polysulfone resin, a fluorene-modified polycarbonate resin, an alicyclic modified polycarbonate resin, and a fluorene ring-modified polyester resin.

The elastomer is not particularly limited, and examples thereof include an elastomer including a repeating unit derived from styrene (polystyrene elastomer), a polyester elastomer, a polyolefin elastomer, a polyurethane elastomer, a polyamide elastomer, a polyacrylic elastomer, a silicone elastomer, and a polyimide elastomer. The elastomer may be a hydrogenated product.

Examples of the polystyrene elastomer include a styrene-butadiene-styrene block copolymer (SBS), a styrene-isoprene-styrene block copolymer (SIS), a polystyrene-poly(ethylene-propylene) diblock copolymer (SEP), a polystyrene-poly(ethylene-propylene)-polystyrene triblock copolymer (SEPS), a polystyrene-poly(ethylene-butylene)-polystyrene triblock copolymer (SEBS), and a polystyrene-poly(ethylene/ethylene-propylene)-polystyrene triblock copolymer (SEEPS).

In addition, the liquid crystal polymer substrate may include components other than the above-described components. Examples of the other components include a crosslinking component, a compatible component, a plasticizer, a stabilizer, a lubricant, and a colorant.

As physical properties and a manufacturing method of the liquid crystal polymer substrate, physical properties and a manufacturing method of a liquid crystal polymer film described in paragraphs “0027” to “0034” of WO2018/163999A can be used.

As the liquid crystal polymer substrate, for example, a commercially available product such as PELLICULE LCP (trade name) manufactured by Chiyoda Integre Co., Ltd. can be used.

(Fluoropolymer Substrate)

The fluoropolymer forming the fluoropolymer substrate is not particularly limited. For example, polytetrafluoroethylene (PTFE), polyvinylidene fluoride (PVdF), a tetrafluoroethylene/hexafluoropropylene copolymer (FEP), a tetrafluoroethylene/perfluoro(alkyl vinyl ether) copolymer (PFA), or an ethylene/tetrafluoroethylene copolymer (ETFE) is preferable.

As the fluoropolymer, for example, tetrafluoroethylene/perfluoro(alkyl vinyl ether) copolymers described in paragraphs “0024” to “0041” of JP2013-078947A, JP2002-053620A, and WO97/021779A are also preferable.

The content of the fluoropolymer in the fluoropolymer substrate with respect to the total mass of the fluoropolymer substrate is preferably 40 mass % or more and more preferably 60 mass % or more and, from the viewpoint of further improving dielectric characteristics, is still more preferably 80 mass % or more. The upper limit value is, for example, 100 mass % or less and is preferably 99 mass % or less and more preferably 97 mass % or less.

In addition, the fluoropolymer substrate may include components other than the above-described components. Examples of the other components include a polymer other than the inorganic filler and the fluoropolymer, a crosslinking component, a compatible component, a plasticizer, a stabilizer, a lubricant, and a colorant. Examples of the polymer other than the inorganic filler and the fluoropolymer include the above-described inorganic fillers and the other polymers which may be included in the liquid crystal polymer.

<Inorganic Oxide Layer>

The inorganic oxide layer is not particularly limited as long as it includes an inorganic oxide.

Examples of the kind of the inorganic oxide forming the inorganic oxide layer include silicon oxide, aluminum oxide, tin oxide, magnesium oxide, silicon oxynitride, silicon carbide oxide, and a mixture thereof. Among these, silicon oxide or aluminum oxide is preferable, and silicon oxide is more preferable. The silicon oxide may be any one of SiO, SiO₂, or a mixture thereof.

The silicon carbide oxide refers to an inorganic silicon compound represented by SiOxCy in a state where a Si atom, an O atom, and a C atom are randomly bonded.

In addition, it is preferable that the inorganic oxide layer includes a silicon atom as a major component. Here, “including a silicon atom as a major component” represents that, in the inorganic oxide layer, an atom having a highest content (atom %) among components selected from metal atoms and metalloid atoms (examples of the metalloid atoms include a boron atom, a silicon atom, a germanium atom, an arsenic atom, an antimony atom, a tellurium atom, a polonium atom, and an astatine atom) is a silicon atom.

A method of forming the inorganic oxide layer is not particularly limited, and examples thereof include a vacuum deposition method, a sputtering method, an ion plating method, and a plasma chemical vapor deposition method (CVD). In particular, a plasma chemical vapor deposition method (hereinafter, also referred to as “plasma CVD method”) is preferable from the viewpoint of further improving adhesiveness with the metal layer, and an atmospheric pressure plasma CVD method is more preferable from the viewpoint that pressure reduction is unnecessary and the atmospheric pressure plasma CVD method is more suitable for continuous production.

In a case where the inorganic oxide layer is formed using a method other than the plasma CVD method, it is preferable that, before forming the inorganic oxide layer on the substrate, a surface of the substrate is roughened through a treatment such as a corona discharge treatment, an UV irradiation treatment, an alkaline solution treatment, or a sand blasting treatment.

Hereinafter, the method of forming the inorganic oxide layer using the plasma CVD method will be described.

The plasma CVD method is a film forming method of decomposing the raw material gas with plasma to deposit the decomposed components on the surface of the substrate.

In a case where the inorganic oxide layer is formed using the plasma CVD method, examples of the raw material gas include monosilane (SiH₄), an organic silicon compound, and an organic aluminum compound.

From the viewpoint of easy gasification, the molecular weight of the organic silicon compound and the organic aluminum compound is preferably 500 or lower and more preferably 30 to 400.

Specific examples of the organic silicon compound include tetraethoxysilane (TEOS), hexamethyldisilazane (HMDS), dimethyl disilazane, trimethyl disilazane, tetramethyl disilazane, pentamethyl disilazane, tetramethoxysilane (TMOS), hexamethyldisiloxane, 1,1,3,3-tetramethyldisiloxane, vinyltrimethylsilane, methyltrimethylsilane, hexamethyldisilane, methylsilane, dimethylsilane, trimethylsilane, diethylsilane, propylsilane, phenylsilane, vinyltriethoxysilane, vinyl trimethoxysilane, phenyltrimethoxysilane, methyltriethoxysilane, and octamethylcyclotetrasiloxane.

As the organic silicon compound, tetraethoxysilane is preferable from the viewpoint of improving handleability.

These organic silicon compounds may be used alone or in combination of two or more kinds.

Examples of the organic aluminum compound include trimethylaluminum, aluminum ethylate, aluminum isopropylate, aluminum diisopropylate mono sec-butyrate, aluminum sec-butyrate, aluminum ethylacetoacetate diisopropylate, aluminum trisethylacetoacetate, aluminum alkylacetoacetate diisopropylate, aluminum bisethylacetoacetate monoacetylacetonate, and aluminum trisacetylacetonate.

As the organic aluminum compound, trimethylaluminum is more preferable from the viewpoint of improving handleability.

These organic aluminum compounds may be used alone or in combination of two or more kinds.

In a case where the inorganic oxide layer is formed using the plasma CVD method, as the major component of the raw material gas, monosilane or an organic silicon compound is preferable, an organic silicon compound is more preferable, and tetraethoxysilane is still more preferable. Here, the major component of the raw material gas refers to a component having the highest content (vol %) among gas species in the raw material gas.

In particular, it is preferable that the raw material gas includes an organic silicon compound (preferably, tetraethoxysilane) as the major component, and the content of the organic silicon compound (preferably tetraethoxysilane) with respect to the total volume of the raw material gas is preferably 80 vol % or more and more preferably 90 vol % or more. The upper limit value is not particularly limited and is, for example, 100 vol % or less.

In addition, in a case where the inorganic oxide layer is formed using the plasma CVD method, a reactant gas such as oxygen or ozone with which an oxide can be formed, a carrier gas, or a gas for discharge may be used together with the raw material gas. As the carrier gas and the gas for discharge, a noble gas such as argon, helium, neon, or xenon, hydrogen, or nitrogen can be used.

In a case where the inorganic oxide layer is formed using the plasma CVD method, the pressure (vacuum degree) of a space where plasma CVD is performed can be appropriately adjusted depending on the kind of the raw material gas and the like, and is preferably 1 Pa to 101300 Pa (atmospheric pressure) and more preferably the atmospheric pressure from the viewpoint that pressure reduction is unnecessary and the pressure is more suitable for continuous production.

The thickness of the inorganic oxide layer is not particularly limited and is preferably 100 nm or less from the viewpoint of reducing a difference in mechanical strength from the substrate such that cohesion failure caused by stress concentration can be suppressed. On the other hand, the lower limit value of the thickness of the inorganic oxide layer is not particularly limited and is preferably 1 nm or more from the viewpoint of further improving film formation stability.

<Adhesive Layer>

The adhesive layer is a layer that is formed of an adhesive.

The adhesive is not particularly limited as long as it is an adhesive that can bond the metallic material (for example, the metal foil) for forming the metal layer. The adhesive is preferably an adhesive capable of thermal pressure bonding with the metallic material and more preferably an adhesive including a resin such as a thermosetting resin or a thermoplastic resin as a major component. Here, the major component in the adhesive refers to a component having the highest content (mass %) among components in the adhesive.

The content of the resin in the adhesive with respect to the total mass of the adhesive is preferably 50 mass % or more, more preferably 60 mass % or more, still more preferably 70 mass % or more, still more preferably 80 mass % or more, and still more preferably 85 mass % or more. The upper limit value is not particularly limited and is, for example, 100 mass % or less.

As the resin, a thermosetting resin or a thermoplastic resin is preferable, and a thermosetting resin is more preferable from the viewpoint of easily performing thermal pressure bonding with the metallic material (for example, the metal foil) for forming the metal layer.

Examples of the thermosetting resin include an epoxy resin, an NBR (NBR refers to an abbreviation for acrylonitrile-butadiene rubber)-phenol resin, a phenol-butyral resin, an epoxy-NBR resin, an epoxy-phenol resin, an epoxy-nylon resin, an epoxy-polyester resin, an epoxy-acrylic resin, an acrylic resin, a polyamide-epoxy-phenol resin, a polyimide resin, and a polyimide siloxane-epoxy resin.

Examples of the thermoplastic resin include a polyamide resin, a polyester resin, a polyimide adhesive, and a polyimide siloxane adhesive.

In addition, the adhesive layer may include a thermosetting resin in a semi-cured state (B stage). In other words, the adhesive layer may be in the B stage.

The adhesive layer may include a component (for example, an inorganic filler) other than the resin.

The inorganic filler is not particularly limited, and examples thereof include the same inorganic fillers as those which may be included in the liquid crystal polymer substrate.

The thickness of the adhesive layer is not particularly limited and, from the viewpoint that low dielectric loss tangent characteristics of the substrate, is preferably a value of (substrate thickness×0.8) or less, more preferably a value of (substrate thickness×0.5) or less, and still more preferably a value of (substrate thickness×0.1) or less. The lower limit value is not particularly limited and is, for example, a value of (substrate thickness×0.0001) or more.

A method of forming the adhesive layer is not particularly limited, and examples thereof include a method of applying the adhesive to the inorganic oxide layer using a coater such as an air knife coater, a rod coater, a bar coater, a curtain coater, a gravure coater, an extrusion coater, a die coater, a slide bead coater, or a blade coater and a method of thermally pressure bonding an adhesive sheet and the inorganic oxide layer.

In a case where the adhesive layer is performed using the above-described coater, an adhesive solution obtained by diluting an adhesive with an organic solvent may be used.

In a case where an adhesive layer is formed using the adhesive solution, it is preferable that a method of applying the adhesive solution to the inorganic oxide layer and optionally drying (for example, heating) the coating film is used.

As the adhesive sheet, for example, a commercially available product such as a low-dielectric adhesive sheet (“SAFY”, manufactured by Nikkan Industries Co., Ltd.) may be used.

In the method of thermally pressure bonding an adhesive sheet and the inorganic oxide layer, the temperature of thermal pressure bonding is, for example, 100° C. to 250° C. from the viewpoint of further improving the adhesiveness with the metal layer. In addition, the pressure of thermal pressure bonding is, for example, 0.1 to 10 MPa from the viewpoint of further improving the adhesiveness with the metal layer. In addition, the thermal pressure bonding time is, for example, 5 to 180 minutes.

<Protective Film>

A protective film may be disposed on a surface of the adhesive layer opposite to the inorganic oxide layer.

In a case where the laminated sheet for a metal-clad laminate includes the protective film that is provided on the surface of the adhesive layer opposite to the inorganic oxide layer, the metal layer is formed on the adhesive layer that is exposed after peeling off the protective film during the manufacturing of the metal-clad laminate.

Examples of the protective film include a polyethylene terephthalate film, a polypropylene film, a polystyrene film, and a polycarbonate film.

As the protective film, for example, films described in paragraphs “0083” to “0087” and “0093” of JP2006-259138A may be used.

As the protective film, for example, ALPHAN (registered trade name) FG-201 (manufactured by Oji F-Tex Co., Ltd.), ALPHAN (registered trade name) E-201F (manufactured by Oji F-Tex Co., Ltd.), CERAPEEL (registered trade name) 25WZ (manufactured by Toray Advanced Film Co., Ltd.), or LUMIRROR (registered trade name) 16QS62 (16KS40) (manufactured by Toray Industries Inc.) may be used.

[Method of Manufacturing Laminated Sheet for Metal-Clad Laminate According to First Embodiment]

It is preferable that a method of manufacturing the laminated sheet for a metal-clad laminate according to the first embodiment is not particularly limited and includes a step 1 and a step 2 described below.

Step 1: an inorganic oxide layer forming step of forming an inorganic oxide layer using a plasma chemical vapor deposition method (plasma CVD method) on a surface of a substrate that includes a liquid crystal polymer or a fluoropolymer

Step 2: an adhesive layer forming step of forming an adhesive layer on the inorganic oxide layer

<Step 1>

The step 1 is an inorganic oxide layer forming step of forming an inorganic oxide layer using a plasma chemical vapor deposition method (preferably an atmospheric pressure plasma CVD method) on a surface of a substrate that includes a liquid crystal polymer or a fluoropolymer.

Configurations of the substrate and the inorganic oxide layer are as described above. In addition, a method of forming the inorganic oxide layer using the plasma CVD method is also as described above.

<Step 2>

Step 2: an adhesive layer forming step of forming an adhesive layer on the inorganic oxide layer obtained in the step 1

The configuration of the adhesive layer is as described above. In addition, a method of forming the adhesive layer is also as described above.

[Metal-Clad Laminate and Method of Manufacturing the Same]

Hereinafter, the configuration of the metal-clad laminate according to the embodiment of the present invention will be described as described below. In addition, this manufacturing method will also be described in detail.

[Metal-Clad Laminate According to First Embodiment]

FIG. 2 is a cross-sectional view showing an example of an embodiment of the metal-clad laminate.

A metal-clad laminate 20 includes a substrate 1 that includes a liquid crystal polymer or a fluoropolymer, an inorganic oxide layer 2, a resin layer 4, and a metal layer 5 in this order.

The metal-clad laminate can be formed using the above-described laminated sheet 10 for a metal-clad laminate. Specific examples of the method include a method of thermally pressure bonding the laminated sheet 10 for a metal-clad laminate and the metal foil such as copper foil such that an exposed surface (that is, the surface of the adhesive layer 3 opposite to the inorganic oxide layer 2) of the adhesive layer 3 in the laminated sheet 10 for a metal-clad laminate faces the metal foil. In a case where the laminated sheet 10 for a metal-clad laminate is applied to the metal-clad laminate, it is preferable that the adhesive layer 3 in the laminated sheet 10 for a metal-clad laminate includes a thermosetting resin as a major component. Through the thermal pressure bonding process, the thermosetting resin in the adhesive layer 3 is cured to form the resin layer (cured resin layer) 4.

Hereinafter, the configurations of the resin layer 4 and the metal layer 5 among the layers forming the metal-clad laminate 20 will be described below in detail. The configurations of the substrate 1 and the inorganic oxide layer 2 are the same as those of the substrate 1 and the inorganic oxide layer 2 in the laminated sheet 10 for a metal-clad laminate.

[Resin Layer]

It is preferable that the resin layer includes a resin as a major component.

It is preferable that the resin is obtained by curing the thermosetting resin that may be included in the adhesive layer of the above-described laminated sheet for a metal-clad laminate.

The major component in the resin layer refers to a component having the highest content (mass %) among components in the resin layer.

The content of the resin in the resin layer with respect to the total solid content of the resin layer is preferably 50 mass % or more, more preferably 60 mass % or more, still more preferably 70 mass % or more, still more preferably 80 mass % or more, and most preferably 85 mass % or more. The upper limit value is not particularly limited and is, for example, 100 mass % or less.

The resin layer may include a component (for example, an inorganic filler) other than the resin. The inorganic filler is not particularly limited, and examples thereof include the same inorganic fillers as those which may be included in the liquid crystal polymer substrate.

The thickness of the resin layer is not particularly limited and, from the viewpoint that low dielectric loss tangent characteristics of the substrate, is preferably a value of (substrate thickness×0.8) or less, more preferably a value of (substrate thickness×0.5) or less, and still more preferably a value of (substrate thickness×0.1) or less. The lower limit value is not particularly limited and is, for example, a value of (substrate thickness×0.0001) or more.

[Metal Layer]

The metal in the metal layer is not particularly limited, and a well-known metal can be used.

As the major component (so-called base metal) in the metal layer, for example, a metal such as copper, aluminum, iron, or nickel or an alloy of the metals is preferable. The major component refers to a metal having the highest content (mass %) among metals in the metal layer.

In particular, from the viewpoint of further improving conductivity, it is more preferable that the metal layer includes copper as a major component.

The content of the metal forming the major component in the metal layer is not particularly limited. In general, the content of the metal with respect to the total mass of the metal layer is preferably 80 mass % or more, more preferably 85 mass % or more, and still more preferably 90 mass % or more.

The thickness of the metal layer is not particularly limited and, from the viewpoint of further improving conductivity and/or the viewpoint of easily performing the patterning process, is, for example, preferably 10 to 200 more preferably 10 to 105 μm, and still more preferably 18 to 105 μm.

From the viewpoint of further reducing transmission loss, an arithmetic average roughness Ra of the surface of the metal layer on the resin layer side is preferably 1.0 μm or less and more preferably 0.5 μm or less. In the present specification, “arithmetic average roughness Ra” is measured according to JIS B 0601:2013.

The surface of the metal layer on the resin layer side may undergo a surface treatment such as a roughening treatment, a rust preventing treatment, a heat-resistance treatment, or a chemical resistance treatment.

The surface of the metal layer on the resin layer side may undergo the surface treatment or the like to improve the adhesiveness with the resin layer.

A method of forming the metal layer is not particularly limited, and examples thereof include a method of using the metal foil or the like and a method of using a plating treatment.

[Method of Manufacturing Metal-Clad Laminate According to First Embodiment]

It is preferable that a method of manufacturing the metal-clad laminate according to the first embodiment is not particularly limited and includes a step 3 described below.

Step 3: a metal layer forming step of forming a metal layer by thermally pressure-bonding a metal foil to the adhesive layer in the laminated sheet for a metal-clad laminate.

<Step 3>

The step 3 is a step of forming a metal layer by thermally pressure-bonding a metal foil to the adhesive layer in the above-described laminated sheet for a metal-clad laminate. The configurations of the laminated sheet for a metal-clad laminate and a manufacturing method thereof are as described above. In particular, it is preferable that the laminated sheet for a metal-clad laminate is formed using the manufacturing method including the step 1 and the step 2.

As the metal foil, for example, a copper foil or a copper alloy foil such as an electrolytic copper foil or a rolled copper foil, an aluminum foil or an aluminum alloy foil, a stainless steel foil, or a nickel foil or a nickel alloy foil can be used.

The thickness of the metal foil is not particularly limited and is, for example, preferably 10 to 200 μm, more preferably 10 to 105 μm, and still more preferably 18 to 105 μm.

From the viewpoint of further reducing transmission loss, an arithmetic average roughness Ra of the surface of the metal foil on the adhesive layer side is preferably 1.0 μm or less and more preferably 0.5 μm or less.

From the viewpoint of further improving the adhesiveness with the metal layer, the surface of the metal foil to which the adhesive layer is bonded may undergo a surface treatment such as a roughening treatment, a rust preventing treatment, a heat-resistance treatment, or a chemical resistance treatment, and may further undergo a surface treatment by a silane coupling agent or the like from the viewpoint of further improving the adhesiveness with the metal layer.

The silane coupling agent is not particularly limited, and examples thereof include an epoxy silane coupling agent (for example, 3-glycidoxypropyltrimethoxysilane), an amino silane coupling agent (for example, N-(2-aminoethyl)-3-aminopropyltrimethoxysilane, and a mercapto silane coupling agent (for example, γ-mercaptopropyl trimethoxysilane). The surface treatment by the silane coupling agent or the like can be performed by applying an aqueous solution of the silane coupling agent having an adjusted concentration of, for example, 0.001 to 5 mass % to a surface of the metal foil and heating the coating film.

A method of the thermal pressure bonding between the metal foil and the adhesive layer is not particularly limited. For example, a commercially available thermal pressure bonding device can be used. Heating conditions and pressurization conditions can be appropriately selected depending on the materials to be used.

Regarding the thermal pressure bonding between the metal foil and the adhesive layer, the laminated sheet for a metal-clad laminate and the metal foil are thermally pressure-bonded such that an exposed surface (that is, the surface of the adhesive layer opposite to the inorganic oxide layer) of the adhesive layer in the laminated sheet for a metal-clad laminate faces the metal foil.

In a case where the laminated sheet for a metal-clad laminate is applied to a metal-clad laminate, it is preferable that the adhesive layer in the laminated sheet for a metal-clad laminate includes a thermosetting resin as a major component. Through the thermal pressure bonding process, the thermosetting resin in the adhesive layer is cured to form the resin layer (cured resin layer).

The temperature of thermal pressure bonding is, for example, 100° C. to 250° C. from the viewpoint of further improving the adhesiveness with the metal layer.

The pressure of thermal pressure bonding is, for example, 0.1 to 10 MPa and, from the viewpoint of further improving the adhesiveness with the metal layer, is preferably 1 to 10 MPa.

In addition, the thermal pressure bonding time is, for example, 5 to 180 minutes.

The thermal pressure bonding may be performed multiple times while changing the temperature and the pressure. For example, after laminating the metal foil on the adhesive layer in the laminated sheet for a metal-clad laminate, a main pressure bonding process may be performed.

[Use]

The metal-clad laminate can be used in a form such as a printed wiring board or a flexible printed wiring board (FPC), for example, partially removing the metal layer by dry etching or wet etching.

### EXAMPLES

The present invention will be described in more detail based on the following examples. Materials, used amounts, ratios, treatment details, treatment procedures, and the like shown in the following examples can be appropriately changed within a range not departing from the scope of the present invention. Accordingly, the scope of the present invention is not limited to the following examples.

### Example 1

[Preparation of Laminated Sheet for Metal-Clad Laminate]

<Inorganic Oxide Layer Forming Step>

As the substrate, a liquid crystal polymer film (“PELLICULE LCP” manufactured by Chiyoda Integre Co., Ltd.) having a thickness of 50 μm was used.

By performing an atmospheric pressure plasma treatment [<plasma generation conditions> gas for discharge: Ar (flow rate: 10 L/min), pulse power source: output voltage: 10 kV, frequency: 10 kHz] on a single surface of the substrate and concurrently blowing the single surface of the substrate with gas including TEOS [<raw material gas> TEOS: 20 mg/min, <carrier gas> N₂: 2 L/min], an inorganic oxide layer (SiOx film) having a thickness of 5 nm was formed on the surface of the substrate. The SiOx film refers to a film of one or more silicon oxide compounds selected from the group consisting of SiO and SiO₂.

<Adhesive Layer Forming Step>

A low-dielectric adhesive sheet (“SAFY” manufactured by Nikkan Industries Co., Ltd.) was disposed on a surface of the inorganic oxide layer, and the layers were laminated using a laminator (“vacuum laminator V-130” manufactured by Nikko-Materials Co., Ltd.) under conditions of 140° C. and laminating pressure: 0.4 MPa) for 1 minute. This way, an adhesive layer having a thickness of 25 μm was formed on the surface of the inorganic oxide layer.

[Preparation of Copper-Clad Laminate]

<Metal Layer Forming Step>

(Copper-Clad Laminate Precursor Step)

A copper foil (“CF-T9DA-SV-18” manufactured by Fukuda Metal Foil & Powder Co., Ltd.) was disposed on the adhesive layer such that a surface to be treated was in contact with the adhesive layer, and the layers were laminated using a laminator (“vacuum laminator V-130” manufactured by Nikko-Materials Co., Ltd.) under conditions of 140° C. and laminating pressure: 0.4 MPa) for 1 minute. Through the above-described procedure, a copper-clad laminate precursor was obtained.

(Main Thermal Pressure Bonding Step)

By thermally pressure-bonding the obtained copper-clad laminate precursor using a thermal pressure bonding device (“MP-SNL”, manufactured by Toyo Seiki Seisaku-sho, Ltd.) under conditions 160° C. and 4.5 MPa for 60 minutes, a copper-clad laminate was prepared.

In the obtained copper-clad laminate, the thickness of the inorganic oxide layer (SiOx film) was 5 nm, the thickness of the resin layer derived from the adhesive layer was 25 μm, and the thickness of the metal layer was 18 μm.

[Evaluation]

<Preparation of Specimen>

The obtained copper-clad laminate was cut into a striped shape of 1 cm×5 cm to prepare a specimen.

<Peel Strength Test>

Using the obtained specimen, a peel strength test was performed at a rate of 50 mm/min. As a result of the test, the peel strength of the metal layer was 9 N/cm, and the peeling mode was cohesion failure of the resin layer.

### Comparative Example 1

A copper-clad laminate and a specimen thereof were prepared using the same method as that of Example 1, except that the adhesive layer was directly formed on the surface of the substrate without performing <Inorganic Oxide Layer Forming Step>, and the peel strength test was performed. As a result of the test, the peel strength of the metal layer was 3 N/cm, and the peeling mode was interfacial peeling of the resin layer and the liquid crystal polymer film.

### Comparative Example 2

A copper-clad laminate and a specimen thereof were prepared using the same method as that of Example 1, except that in <Inorganic Oxide Layer Forming Step>, only the atmospheric pressure plasma treatment was performed on the single surface of the substrate and the TEOS gas was not used, and the peel strength test was performed. As a result of the test, the peel strength of the metal layer was 4 N/cm, and the peeling mode was cohesion failure of the liquid crystal polymer film.

### EXPLANATION OF REFERENCES

10: laminated sheet for a metal-clad laminate
20: metal-clad laminate
1: substrate
2: inorganic oxide layer
3: adhesive layer
4: resin layer
5: metal layer

What is claimed is:

1. A laminated sheet for a metal-clad laminate comprising:
a substrate that includes a liquid crystal polymer or a fluoropolymer;
an inorganic oxide layer; and
an adhesive layer,
wherein the substrate, the inorganic oxide layer, and the adhesive layer are laminated in this order.

2. The laminated sheet for a metal-clad laminate according to claim 1,
wherein the adhesive layer includes a resin as a major component.

3. The laminated sheet for a metal-clad laminate according to claim 1,
wherein the adhesive layer is in the B stage.

4. The laminated sheet for a metal-clad laminate according to claim 1,
wherein in the inorganic oxide layer, an atom having a highest content among components selected from metal atoms and metalloid atoms is a silicon atom.

5. A method of manufacturing a laminated sheet for a metal-clad laminate, the method comprising:
an inorganic oxide layer forming step of forming an inorganic oxide layer using a plasma chemical vapor deposition method on a surface of a substrate that includes a liquid crystal polymer or a fluoropolymer; and
an adhesive layer forming step of forming an adhesive layer on the inorganic oxide layer.

6. The method of manufacturing a laminated sheet for a metal-clad laminate according to claim 5,
wherein the inorganic oxide layer is formed using a raw material gas including tetraethoxysilane as a major component.

7. The method of manufacturing a laminated sheet for a metal-clad laminate according to claim 5,
wherein the plasma chemical vapor deposition method is an atmospheric pressure plasma chemical vapor deposition method.

8. The method of manufacturing a laminated sheet for a metal-clad laminate according to claim 5,
wherein the adhesive layer includes a resin as a major component.

9. The method of manufacturing a laminated sheet for a metal-clad laminate according to claim 5,
wherein the adhesive layer is in the B stage.

10. A method of manufacturing a metal-clad laminate, the method comprising:
a metal layer forming step of forming a metal layer by thermally pressure-bonding a metal foil to the adhesive layer in the laminated sheet for a metal-clad laminate according to claim 1.

11. A method of manufacturing a metal-clad laminate, the method comprising:
a step of manufacturing a laminated sheet for a metal-clad laminate using the method of manufacturing a laminated sheet for a metal-clad laminate according to claim 5; and
a metal layer forming step of forming a metal layer by thermally pressure-bonding a metal foil to the adhesive layer in the laminated sheet for a metal-clad laminate.

12. A metal-clad laminate comprising:
a substrate that includes a liquid crystal polymer or a fluoropolymer;
an inorganic oxide layer;
a resin layer; and
a metal layer,
in which the substrate, the inorganic oxide layer, and the metal layer are laminated in this order.

13. The laminated sheet for a metal-clad laminate according to claim 2,
wherein the adhesive layer is in the B stage.

14. The laminated sheet for a metal-clad laminate according to claim 2,
wherein in the inorganic oxide layer, an atom having a highest content among components selected from metal atoms and metalloid atoms is a silicon atom.

15. The method of manufacturing a laminated sheet for a metal-clad laminate according to claim 6,
wherein the plasma chemical vapor deposition method is an atmospheric pressure plasma chemical vapor deposition method.

16. The method of manufacturing a laminated sheet for a metal-clad laminate according to claim 6,
wherein the adhesive layer includes a resin as a major component.

17. The method of manufacturing a laminated sheet for a metal-clad laminate according to claim 6,
wherein the adhesive layer is in the B stage.

18. A method of manufacturing a metal-clad laminate, the method comprising:
a metal layer forming step of forming a metal layer by thermally pressure-bonding a metal foil to the adhesive layer in the laminated sheet for a metal-clad laminate according to claim 2.

19. A method of manufacturing a metal-clad laminate, the method comprising:
a step of manufacturing a laminated sheet for a metal-clad laminate using the method of manufacturing a laminated sheet for a metal-clad laminate according to claim 6; and
a metal layer forming step of forming a metal layer by thermally pressure-bonding a metal foil to the adhesive layer in the laminated sheet for a metal-clad laminate.

20. The laminated sheet for a metal-clad laminate according to claim 3,
wherein in the inorganic oxide layer, an atom having a highest content among components selected from metal atoms and metalloid atoms is a silicon atom.
